(19) United States
(12) Patent Application Publication
(10) Pub. No.: US 2009/0094783 A1
(43) Pub. Date: Apr. 16, 2009

(54) FIBERGLASS CLOTH TAPE LAMINATED FIBERBOARD BARRIER

(76) Inventor: Raymond P. Dudderar, Stanford, KY (US)

Correspondence Address: KING & SCHICKLI, PLLC, 247 NORTH BROADWAY, LEXINGTON, KY, 40507, US

(21) Appl. No.: 12/243,349

(22) Filed: Oct. 1, 2008

Related U.S. Application Data
(60) Provisional application No. 60/979,216, filed on Oct. 11, 2007.

(51) Int. Cl. A47L 5/00; A47L 9/22; H05K 9/00

(52) U.S. Cl. 15/327.2; 15/412; 174/377

(57) ABSTRACT

A floorcare apparatus includes a nozzle assembly having a suction inlet and a canister assembly connected to the nozzle assembly. A dirt collection vessel is carried on the canister assembly. A suction generator is carried on one of the nozzle assembly and the canister assembly. Additionally, an electrical component is carried on the apparatus. Further, the apparatus is characterized by a housing for the electrical component wherein the housing includes a cavity and a wall constructed from a first structural layer covered by a layer of fiberglass cloth tape.

This application claims the benefit of U.S. Provisional Patent Application Ser. No. 60/979,216 filed on 11 Oct. 2007.

### TECHNICAL FIELD AND INDUSTRIAL APPLICABILITY OF THE INVENTION

The present invention relates generally to the floor care appliance field, more particularly, to a floor care apparatus including a novel electrical component housing.

### BACKGROUND OF THE INVENTION

Floor care appliances such as canister vacuum cleaners, upright vacuum cleaners and extractors have long been known in the art. In recent years a trend has developed with manufacturers equipping the apparatus or appliances with more powerful drive motors to provide enhanced cleaning action. The higher operating amperages characteristic of these units has resulted in increased temperatures being generated by electrical components of the units. The present invention relates to a housing for electrical components particularly useful in floor care apparatus. The housing advantageously provides increased fire protection.

### SUMMARY OF THE INVENTION

In accordance with the purposes of the present invention as described herein, an improved floor care apparatus is provided. The floor care apparatus comprises a nozzle assembly including a suction inlet, a canister assembly connected to the nozzle assembly, a dirt collection vessel carried on the canister assembly, a suction generator carried on the canister assembly or the nozzle assembly and an electrical component carried on the apparatus. The apparatus is characterized by a housing including a cavity that holds the electrical component. A wall of that housing is constructed from a first structural layer covered by a layer of fiberglass cloth tape. More specifically, the fiberglass cloth tape is a V-0 rated tape.

More specifically describing the invention, the first structural layer of the housing is constructed from a material selected from a group consisting of fiberboard, ABS, polycarbonate, polypropylene and combinations thereof. The fiberglass cloth tape includes silicone adhesive and about 90 to about 100 weight percent fiberglass. The cavity may be fully enclosed or open. Further, the housing for the electrical component may be carried on the canister assembly or the nozzle assembly. The electrical component housed in the cavity may include a circuit board, a triac or a circuit board and a triac.

In accordance with an additional aspect of the present invention a housing is provided for an electrical component. The housing comprises a wall forming a cavity. The wall is constructed from a first structural layer covered by a layer of fiberglass cloth tape. The first structural layer is made from a material selected from a group consisting of fiberboard, ABS, polycarbonate, polypropylene and combinations thereof while the fiberglass tape includes between about 90 and about 100 weight percent fiberglass.

In accordance with still another aspect of the present invention a method is provided of compartmentalizing an electrical component in a floor care apparatus. The method comprises providing a housing for the electrical component on the floor care apparatus and constructing a wall of that housing from a first structural layer covered by a layer of fiberglass cloth tape. Still further, the method also comprises the step of selecting the first structural layer from a material selected from a group consisting of fiberboard, ABS, polycarbonate, polypropylene and combinations thereof. In addition, the method includes using a V-0 rated fiberglass cloth tape.

In the following description there is shown and described several different embodiments of the invention, simply by way of illustration of some of the modes best suited to carry out the invention. As it will be realized, the invention is capable of other different embodiments and its several details are capable of modification in various, obvious aspects all without departing from the invention. Accordingly, the drawings and descriptions will be regarded as illustrative in nature and not as restrictive.

### BRIEF DESCRIPTION OF THE DRAWINGS

The accompanying drawings incorporated herein and forming a part of the specification, illustrate several aspects of the present invention and together with the description serve to explain certain principles of the invention. In the drawings:

FIG. 1a is a front perspective view of an upright vacuum cleaner constructed in accordance with the teachings of the present invention;

FIG. 1b is a rear perspective view of the vacuum cleaner illustrated in FIG. 1a.

FIG. 2 is a schematical view of the dirt collection vessel provided on the vacuum cleaner;

FIG. 3 is a schematical air flow diagram of the vacuum cleaner of the present invention;

FIG. 4 is a detailed, partially cross-sectional schematical view of the housing holding an electrical component; and

FIG. 5 is a view similar to FIG. 4 showing an alternative embodiment of the housing and electrical component including a heat sink;

Reference will now be made in detail to the present preferred embodiments of this invention, examples of which are illustrated in the accompanying drawings.

### DETAILED DESCRIPTION OF THE PREFERRED EMBODIMENTS OF THE INVENTION

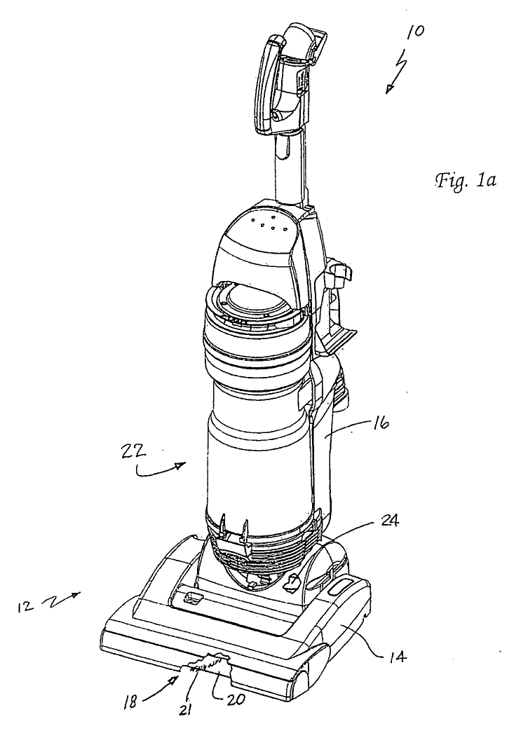

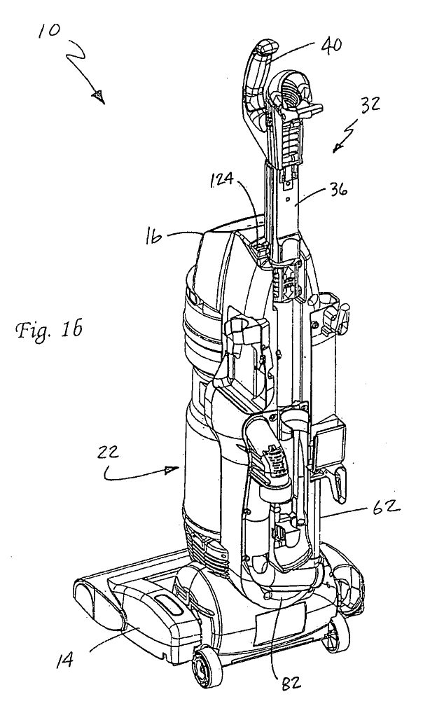

Reference is now made to FIGS. 1a and 1b showing a floor care apparatus 10 of the present invention. As illustrated, that apparatus 10 is an upright vacuum cleaner. It should be appreciated that while a specific upright vacuum cleaner 10 is illustrated, embodiments of the present invention also include different upright vacuum cleaners, canister vacuum cleaners and extractors constructed in accordance with the teachings of the present invention.

The upright vacuum cleaner 10 includes a housing, generally designated by reference numeral 12, comprising a nozzle assembly 14 and a canister assembly 16. The nozzle assembly 14 includes a suction inlet 18. The nozzle assembly 14 may also carry a rotary agitator 20 adjacent the suction inlet 18. The rotary agitator 20 includes cleaning elements 21 such as brushes, bristle tufts, heater bars or the like. As the rotary agitator 20 rotates, the cleaning elements 21 engage the nap of an underlying rug or carpet and serve to sweep dirt and debris into the suction inlet 18 in a manner well known in the art. The canister assembly 16 carries a dirt collection vessel, generally designated by reference numeral 22, and a suction generator 24 including a drive motor 52.

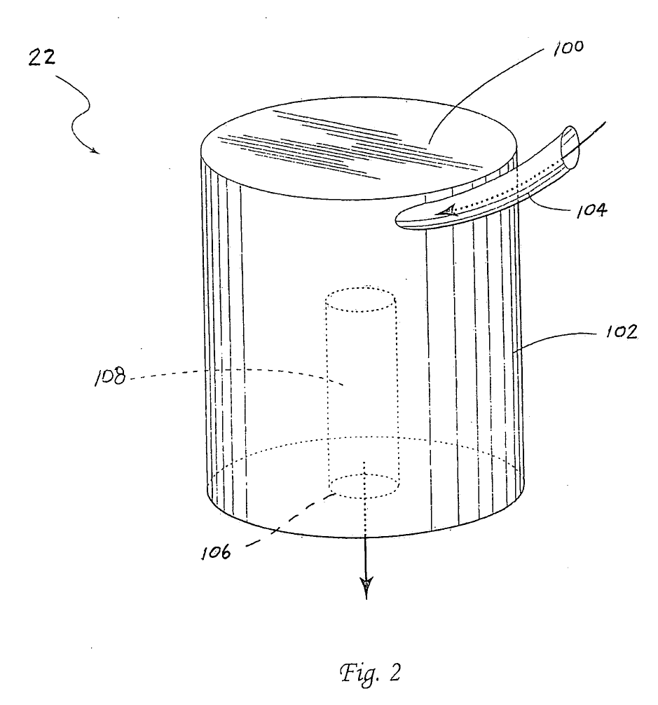

The dirt collection vessel 22 may take the form of a filter bag (not shown) such as a standard vacuum cleaner bag, which traps dirt and debris but includes pores to allow the passage of air through the bag. Alternatively, the dirt collection vessel 22 may take the form of a dirt cup 100 as schematically illustrated in FIG. 2. That dirt cup 100 may include a cylindrical dirt collection chamber 102, a tangentially directed inlet 104 and an axially directed outlet 106 in order to provide for cyclonic air flow and the cleaning benefits associated with that air flow that are well known in the art. If desired, a primary filter 108 may be provided in that dirt cup 100 over the axially directed outlet 106.

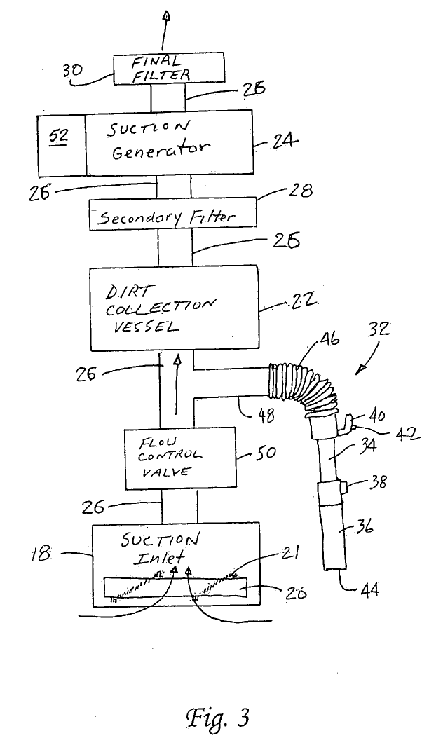

As best illustrated in FIG. 3, a first air flow pathway 26 connects and provides fluid communication between the suction inlet 18, the dirt collection vessel 22 and the suction generator 24. A secondary filter 28 may be provided in the first air flow pathway 26 between the dirt collection vessel 22 and the suction generator 24. In addition, a final filter 30, such as a HEPA filter, may be provided in the first air flow pathway 26 downstream from the suction generator 24. The final filter 30 cleans any remaining dirt and debris from the air stream passing through the vacuum cleaner 10 before that air stream is returned to the environment. This includes any carbon particles that might have been picked up in the air stream after it passes over the motor of the suction generator 24 in order to provide cooling.

A cleaning wand assembly, generally designated by reference numeral 32 is carried on the housing 12 of the vacuum cleaner. As best illustrated in FIGS. 1b and 3, the cleaning wand assembly 32 includes two telescoping tubular sections 34, 36 and a cooperating latching mechanism 38 that allows one to lengthen or shorten the wand assembly 32 as desired. The telescoping wand assembly 32 may be constructed similar to that illustrated in U.S. Pat. No. 6,148,474 to Ohara et al, the full disclosure of which is incorporated herein by reference. The wand assembly 32 also includes a control handle 40 that may be equipped with an on/off switch 42 and any other control switching for the vacuum cleaner 10 as desired. A flexible hose 46 connects the handle end of the cleaning wand assembly 32 to a second air flow pathway 48 carried on the housing 12 which is connected to and provides fluid communication with the first air flow pathway 26 between the dirt collection vessel 22 and a flow control valve generally designated by reference numeral 50. The flow control valve 50 may be of the type described in detail in co-pending U.S. patent application Ser. No. 11/683,485 filed on 8 Mar. 2007 and fully incorporated herein by reference. Such a valve 50 allows the operator to select between a normal floor cleaning mode of operation using the nozzle assembly 14 and an above floor cleaning nozzle using the wand assembly 32.

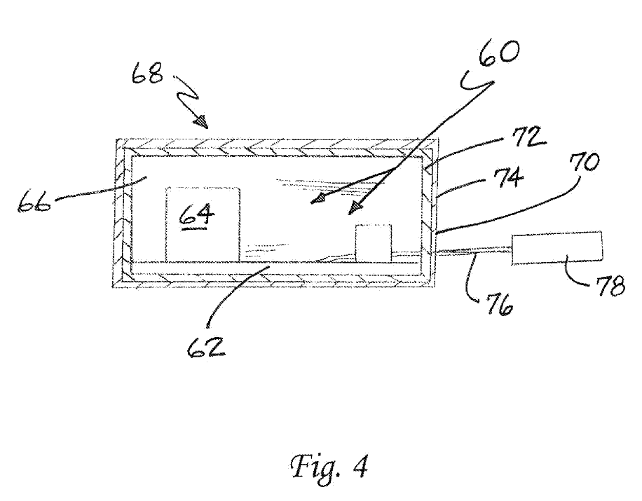

The drive motor 52 of the suction generator 24 is controlled by an electrical component 60 (see FIG. 4). In the illustrated embodiment, the electrical component 60 includes a printed circuit board 62 and a triac 64. As illustrated, the electrical component 60 is received in a cavity 66 formed in a housing 68. It should be appreciated that the cavity 66 may be fully enclosed by the housing 68 or one or more sides of the cavity may be open. An electrical line 76 connects the electrical component 60 to an electrical connector 78.

As illustrated, the housing 68 is formed by at least one wall 70. The wall. 70 is constructed from a first structural layer 72 covered by a layer of fiberglass cloth tape 74. More specifically, the first structural layer may be constructed from a material selected from a group consisting of fiberboard, ABS, polycarbonate, polypropylene and combinations thereof. The fiberglass cloth tape 74 includes between about 90 and about 100 weight percent fiberglass. Preferably, the fiberglass cloth tape is a V-0 rated material. One fiberglass cloth tape 74 useful in the present invention is manufactured by IDEAL TAPE COMPANY and sold under the designation IT-7300 Fiberglass Tape.

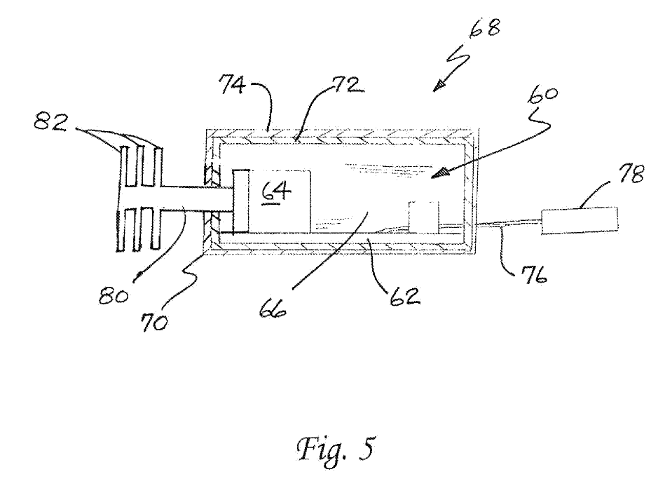

An alternative embodiment is illustrated in FIG. 5. The housing 68 of the FIG. 5 embodiment incorporates a wall 70 including a first structural layer 72 and a fiberglass cloth tape covering 74 as described in detail above with respect to the first embodiment illustrated in FIG. 4. The electrical component 60 is held in a cavity 66 in the housing 68. The only difference between the FIG. 5 embodiment and the FIG. 4 embodiment is the presence of a heat sink 80 connected to the triac 64 held in the cavity 66 of the housing 68. As illustrated the heat sink 80 projects outwardly from the housing. Thus, the heat dissipating fins 82 may be positioned in an air flow path of the vacuum cleaner 10 such as the conduit 26 in order to quickly dissipate heat generated by the triac 64.

The foregoing description of the preferred embodiments of the present invention have been presented for purposes of illustration and description. It is not intended to be exhaustive or to limit the invention to the precise form disclosed. Obvious modifications or variations are possible in light of the above teachings. For example, while the heat sink 80 in the illustrated embodiment is connected to the triac 64, it should be appreciated that the heat sink could be connected to the housing 68 if desired. Further it should be appreciated that the housing 68 may be positioned in either the nozzle assembly 14 or the canister assembly 16: wherever appropriate in order to house an electrical component 60 on the apparatus 10.

The embodiments were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled. The drawings and preferred embodiments do not and are not intended to limit the ordinary meaning of the claims in their fair and broad interpretation in any way.

What is claimed:

1. A floor care apparatus, comprising:
a nozzle assembly including a suction inlet;
a canister assembly connected to said nozzle assembly;
a dirt collection vessel carried on said canister assembly;
a suction generator carried on one of said nozzle assembly and said canister assembly; and
an electrical component carried on said apparatus;
said apparatus being characterized by a housing for said electrical component wherein said housing includes a cavity and a wall constructed from a first structural layer covered by a layer of fiberglass cloth tape.

2. The apparatus of claim 1, wherein said first structural layer is constructed from a material selected from a group consisting of fiberboard, ABS, polycarbonate, polypropylene and combinations thereof.

3. The apparatus of claim 1, wherein said electrical component includes a circuit board.

4. The apparatus of claim 1, wherein said electrical component includes a triac.

5. The apparatus of claim 1, wherein said electrical component includes a circuit board and a triac.

6. The apparatus of claim 1, wherein said fiberglass cloth tape includes between about 90 and about 100 weight percent fiberglass.

7. The apparatus of claim 1, wherein said housing for said electrical component is carried on said canister assembly.

8. The apparatus of claim 1, wherein said housing for said electrical component is carried on said nozzle assembly.

9. The apparatus of claim 1, wherein said fiberglass cloth tape is V-0 rated.

10. The apparatus of claim 1, wherein said cavity is enclosed.

11. The apparatus of claim 1, wherein said cavity is open.

12. The apparatus of claim 1, further including a heat sink connected to said electrical component and projecting from said housing.

13. A housing for an electrical component, comprising:
a wall forming a cavity, said wall being a wall constructed from a first structured layer covered by a layer of fiberglass cloth tape.

14. The housing of claim 13, wherein said first structural layer is made from a material selected from a group consisting of fiberboard, ABS, polycarbonate, polypropylene and combinations thereof.

15. The housing of claim 14, wherein said fiberglass cloth tape is V-0 rated and includes between about 90 and about 100 weight percent fiberglass.

16. A method of compartmentalizing an electrical component in a floor care apparatus, comprising:
providing a housing for said electrical component on said floor care apparatus; and
constructing a wall of said housing from a first structural layer covered by a layer of fiberglass cloth tape.

17. The method of claim 16, comprising selecting said first structural layer from a material selected from a group consisting of fiberboard, ABS, polycarbonate, polypropylene and combinations thereof.

18. The method of claim 17 including using a V-0 rated fiberglass cloth tape.
